(19) United States
(12) Patent Application Publication
(10) Pub. No.: US 2025/0226316 A1
(43) Pub. Date: Jul. 10, 2025

(54) DRAM CELL STRUCTURE AND METHOD FOR MANUFACTURING THE SAME

(71) Applicant: ETRON TECHNOLOGY, INC., Hsinchu (TW)

(72) Inventors: Ming-Hong KUO, Hsinchu (TW); Chun-Nan LU, Hsinchu (TW)

(73) Assignee: ETRON TECHNOLOGY, INC., Hsinchu (TW)

(21) Appl. No.: 19/002,311

(22) Filed: Dec. 26, 2024

Related U.S. Application Data
(60) Provisional application No. 63/618,384, filed on Jan. 8, 2024.

(51) Int. Cl. H01L 23/528; H01L 21/762; H01L 21/768; H10B 12/00

(52) U.S. Cl. CPC H01L 23/5283; H01L 21/76224; H01L 21/76877; H10B 12/482; H10B 12/488

(57) ABSTRACT

DRAM cell structures and methods for manufacturing the same are provided. The DRAM cell structure includes a semiconductor substrate having a well region and an original semiconductor surface, an access transistor located within the well region and having a gate structure, a bit line electrically coupled to the access transistor, a storage capacitor electrically coupled to the access transistor, a word line electrically coupled to the gate structure of the access transistor, an isolation structure within the well region and surrounding the access transistor, and a conductive interconnection structure positioned within the isolation structure and electrically connected to the well region of the semiconductor substrate.

This application claims the benefits of U.S. Provisional Application No. 63/618,384, filed on Jan. 8, 2024, the subject matters of which are incorporated herein by reference.

### BACKGROUND

### Technical Field

The disclosure relates to a memory cell structure and a method for manufacturing the same, and more particularly to a dynamic random-access memory (DRAM) cell structure with an embedded interconnection structure for the well region of DRAM and a method for manufacturing the same.

### Description of the Related Art

Each DRAM cell includes an access transistor and a storage capacitor, the gate of the access transistor is electrically coupled to a word line (WL) and a sense amplifier is electrically coupled to the access transistor through a bit line (BL). The DRAM cell uses the access transistor as a switch to control the charges to be stored from the bit line (BL) into the storage capacitor in WRITE mode or to be transferred out to bit line in READ mode. Therefore, the access transistor requires good control to provide stable switch in WRITE/READ mode and also need low leakage while the access transistor in turn-off state to avoid loss of charge in the storage capacitor. As such, the apply voltage on access transistor should meet designed level with less influence by parasitic resistance in interconnection.

An example for the voltages applied to the access transistor is provided in TABLE 1. WL (word line), as a control gate of the access transistor, can be set to 2.8V for device turn-on and can be set to −0.2V for device turn-off. BL (bit line), as a drain side of the access transistor, can be set to 1.0V for writing charges into storage capacitor to meet “High” state and can be set to 0V for discharge storage capacitor to perform “Low” state. When DRAM cell is in standby mode (without operation), BL(bit line) will keep in “Equalization” state that is in the middle of “High” state and “Low” state. The well region where the access transistor is located can not be floating. The well region need to be connected to a voltage level to ensure good control of the device turn-on and turn-off, and have good control to the device leakage current to prevent storage charge loss.

TABLE 1

| Components | Volt (V) |
|---|---|
| WL(Word Line) On | 2.8 |
| WL(Word Line) Off | −0.2 |
| BL(Bit Line) in “High” state | 1.0 |
| BL(Bit Line) in “Low” state | 0.0 |
| BL(Bit Line) in “Equalization” state | 0.5 |
| Well region | −0.7 |

FIG. 1a illustrates a conventional DRAM cell structure with a metal contact at memory cell array boundary. FIG. 1b illustrates a schematic top view of a conventional DRAM cell structure 1. FIG. 1c is a schematic cross-sectional view of the conventional DRAM cell structure 1 illustrated along the lines AA′ shown in FIG. 1b. The conventional DRAM cell structure 1 includes a substrate 2, three sets of active areas 4 in the substrate 2, two isolation structures 6 in the substrate 2, three sets of word lines 7S in the substrate 2, bit lines 9 above the substrate 2, bit line contacts 8 above the substrate 2. The semiconductor substrate 2 has a well region 2W. Each set of active areas 4 includes active areas AA arranged along a first direction D1 and separated from each other. The active areas AA are within the well region 2W of the semiconductor substrate 2. The access transistors of the DRAM cell structure 1 are formed in the active areas AA. The isolation structure 6 are positioned between two sets of active areas 4 and within the well region 2W. Each set of word lines 7S includes a pair of word lines 7. The word lines 7 are arranged along a second direction D2 perpendicular to the first direction D1. The word lines 7 extends across the active areas AA. The bit lines 9 are arranged along the first direction D1. The bit lines 9 extend across the sets of active areas 4 and the sets of word lines 7S. The bit line contacts 8 are positioned in intersections of active areas AA and bit lines 9. The isolation structures 6, the word lines 7 can be below the original semiconductor surface of the substrate 2 in the third direction D3 perpendicular to the first direction D1 and the second direction D2. The isolation structures 6, the word lines 7 can be embedded in the substrate 2. In the conventional DRAM cell structure, the well region where the access transistor is located is connected to voltage source through a metal contact at memory cell array boundary or at a memory cell array block boundary and a metal line, and the voltage from the voltage source is distributed to each memory cell directly through the well region.

However, the resistance of this electrical connection through the well region (made of lower doped semiconductor) in the conventional DRAM cell structure is usually higher due to this electrical connection has long path and the doping concentration of the well region is low. Once the doping concentration of the well region, the DRAM cell structure or the size of the DRAM cell array block changes, the performance of the access transistor may be affected. Moreover, since there are many components above the well region, a large number of metal contacts for a DRAM cell array block must be provided, as shown in FIG. 2.

### SUMMARY

An embodiment of the present disclosure provides a DRAM cell structure. The DRAM cell structure includes a semiconductor substrate having a well region and an original semiconductor surface, an access transistor located within the well region and having a gate structure, a bit line electrically coupled to the access transistor, a storage capacitor electrically coupled to the access transistor, a word line electrically coupled to the gate structure of the access transistor, an isolation structure within the well region and surrounding the access transistor, and a conductive interconnection structure positioned within the isolation structure and electrically connected to the well region of the semiconductor substrate.

According to an aspect of the present disclosure, a bottom surface of the conductive interconnection structure contacts the well region of the semiconductor substrate.

According to an aspect of the present disclosure, a bottom surface of the conductive interconnection structure is lower than a bottom surface of the gate structure.

According to an aspect of the present disclosure, an upper surface of the conductive interconnection structure is covered by the isolation structure and lower than the original semiconductor surface of the semiconductor substrate.

According to an aspect of the present disclosure, the upper surface of the conductive interconnection structure is lower than a bottom surface of the gate structure.

According to an aspect of the present disclosure, the DRAM cell structure further includes a trench in the substrate. The isolation structure and the conductive interconnection structure are in the trench.

According to an aspect of the present disclosure, the word line and the conductive interconnection structure extend along a first direction, and the bit line extends along a second direction different from the first direction.

According to an aspect of the present disclosure, the conductive interconnection structure has a first sidewall and a second sidewall opposite to the first sidewall, both the first sidewall and the second sidewall are covered by the isolation structure.

According to an aspect of the present disclosure, the conductive interconnection structure extends to a position close to a boundary of the well region.

According to an aspect of the present disclosure, the semiconductor substrate further includes a cell array block accommodating the access transistor, and the conductive interconnection structure extends to a position close to a boundary of the cell array block.

According to an aspect of the present disclosure, the DRAM cell structure further includes a metal contact close to the boundary of the cell array block. The metal contact electrically connected to the conductive interconnection structure.

According to an aspect of the present disclosure, the conductive interconnection structure includes highly doped silicon, tungsten, titanium nitride, or combinations thereof.

An embodiment of the present disclosure provides a DRAM cell structure. The DRAM cell structure includes a semiconductor substrate with a well region and an original semiconductor surface, a first set of active areas within the well region, a second set of active areas within the well region, a first word line extending across the first set of active areas, a second word line extending across the second set of active areas, an isolation structure between the first set of active areas and the second set of active areas, and a conductive interconnection structure positioned within the isolation structure and electrically connected to the well region.

According to an aspect of the present disclosure, the first word line, the second word line, and the conductive interconnection structure extend along a first direction.

According to an aspect of the present disclosure, a bottom surface of the conductive interconnection structure contacts the well region of the semiconductor substrate.

According to an aspect of the present disclosure, the semiconductor substrate further includes a cell array block accommodating the first set of active areas and the second set of active areas, and the conductive interconnection structure extends to a position close to a boundary of the cell array block.

According to an aspect of the present disclosure, the DRAM cell structure further includes a metal contact outside the boundary of the cell array block. The metal contact electrically connected to the conductive interconnection structure.

According to an aspect of the present disclosure, an upper surface of the conductive interconnection structure is covered by the isolation structure.

An embodiment of the present disclosure provides a method for manufacturing a DRAM cell structure. The method includes: providing a semiconductor substrate with an original semiconductor surface; defining an active area; forming a trench in the semiconductor substrate and near the active area; forming an isolation structure and a conductive interconnection structure in the trench, wherein the conductive interconnection structure are surrounded by the isolation structure; forming a well region accommodating the active area. A bottom surface of the conductive interconnection structure contacts the well region of the semiconductor substrate. The conductive interconnection structure extends along a first direction and remote from the active area.

According to an aspect of the present disclosure, forming the isolation structure and the conductive interconnection structure in the trench includes: forming a first dielectric material covering sidewalls of the trench; forming the conductive interconnection structure surrounded by the first dielectric material; forming a second dielectric material on an upper surface of the conductive interconnection structure, wherein the first dielectric material and the second dielectric material form the isolation structure.

The above and other embodiments of the disclosure will become better understood with regard to the following detailed description of the non-limiting embodiment(s). The following description is made with reference to the accompanying drawings.

### BRIEF DESCRIPTION OF THE DRAWINGS

FIG. 1a illustrates a conventional DRAM cell structure with a metal contact at memory cell array boundary.

FIG. 1b illustrates a schematic top view of a conventional DRAM cell structure.

FIG. 1c is a schematic cross-sectional view of the conventional DRAM cell structure illustrated along the lines AA′ shown in FIG. 1b.

FIG. 2 illustrates a conventional arrangement of metal contacts for DRAM cell array blocks.

FIG. 3 illustrates a circuit diagram for a DRAM cell structure according to an embodiment of the present disclosure.

FIG. 4 illustrates a schematic top view of a DRAM cell structure according to an embodiment of the present disclosure.

FIG. 5 is a schematic cross-sectional view of the DRAM cell structure illustrated along the lines BB′ shown in FIG. 4.

FIG. 6 is a schematic cross-sectional view of a DRAM cell structure according to another embodiment of the present disclosure.

FIG. 6a is a schematic cross-sectional view of a DRAM cell structure according to yet another embodiment of the present disclosure.

FIG. 7 illustrates an arrangement of conductive interconnection structures for DRAM cell array blocks according to some embodiments of the present disclosure.

FIG. 8 illustrates an arrangement of conductive interconnection structures for DRAM cell array blocks according to some embodiments of the present disclosure.

FIG. 9 to FIG. 19 illustrate schematic cross-sectional views of structures at various stages of a method for manufacturing a DRAM cell structure according to an embodiment of the present disclosure.

FIG. 20 to FIG. 26 illustrate schematic cross-sectional views of structures at various stages of a method for manufacturing a DRAM cell structure according to another embodiment of the present disclosure.

### DETAILED DESCRIPTION

Various embodiments will be described more fully hereinafter with reference to accompanying drawings, which are provided for illustrative and explaining purposes rather than a limiting purpose. For clarity, the components may not be drawn to scale. In addition, some components and/or reference numerals may be omitted from some drawings. It is contemplated that the elements and features of one embodiment can be beneficially incorporated in another embodiment without further recitation. In the following methods for manufacturing semiconductor devices, there may be one or more additional operations between the operations described, and the order of the operations may vary. The illustration uses the same/similar reference numerals to indicate the same/similar elements.

As used in the specification and the appended claims, the ordinals such as “first”, “second” and the like to describe elements do not imply or represent a specific position in the structure, or the order of arrangement, or the order of manufacturing. The ordinals are only used to clearly distinguish multiple elements with the same name. As used in the specification and the appended claims, spatial relation terms such as “on”, “above”, “over”, “upper,” “top”, “below”, “beneath”, “under”, “lower”, “bottom” and the like may be used to describe the relative spatial relations or positional relations between one element(s) and another element(s) as illustrated in the drawings, and these spatial relations or positional relations, unless specified otherwise, can be direct or indirect. The spatial relation terms are intended to encompass different orientations of structures in addition to the orientation depicted in the drawings. The structure can be inverted or rotated by various angles, and the spatial relation descriptions used herein can be interpreted accordingly. As used in the specification and the appended claims, the singular forms “a,” “an,” and “the” are intended to include the plural forms as well, unless the context clearly indicates otherwise. As used in the specification and the appended claims, the term “and/or” includes any and all combinations of one or more of the associated listed items.

Additionally, the term “electrically coupled” used in the specification and claims can refer to an ohmic contact between elements, or current passing through elements, or an operational relation between elements. The operational relation may mean, for example, that one element is used to drive another element, but current may not flow directly between these two elements. As used in the specification and the appended claims, term “deposition” includes, but is not limited to, chemical vapor deposition (CVD), physical vapor deposition (PVD), atomic layer deposition (ALD) and epitaxial growth. Depending on the type of material to be formed, a person of ordinary skill in the art can select an appropriate technology for forming the material. As used in the specification and the appended claims, term “etching” and “etching back” includes, but are not limited to, dry etching and wet etching. As used in the specification and the appended claims, term “polishing process” includes, but is not limited to, a chemical-mechanical planarization (CMP) and an ion milling process. The terms “etching”, “etching back” and “polishing process” used in the specification and the appended claims may replace with each other, and a person of ordinary skill in the art can select an appropriate removal technology depending on the structure and material.

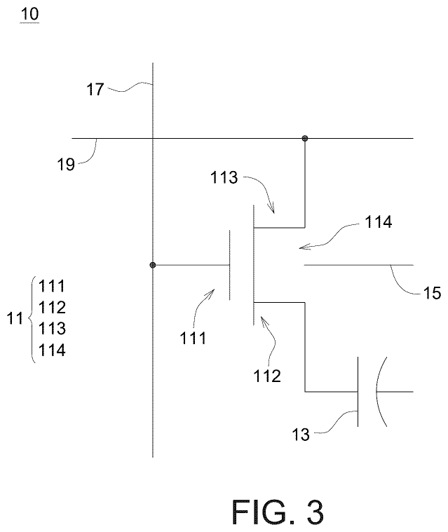

Referring to FIG. 3, FIG. 3 illustrates a circuit diagram for a DRAM cell structure 10 according to an embodiment of the present disclosure. The DRAM cell structure 10 includes an access transistor 11, a storage capacitor 13, a conductive interconnection structure 15, a word line 17 and a bit line 19. The access transistor 11 includes a gate structure 111, a source structure 112 and a drain structure 113. The access transistor 11 is located within a well region 114. The word line 19 is electrically coupled to the gate structure 111 of the access transistor 11. The bit line 19 is electrically coupled to the drain structure 113 of the access transistor 11. The conductive interconnection structure 15 is electrically connected to the well region 114. The storage capacitor 13 is electrically coupled to the source structure 112 of the access transistor 11. The storage capacitor 13 can be positioned above the access transistor 11.

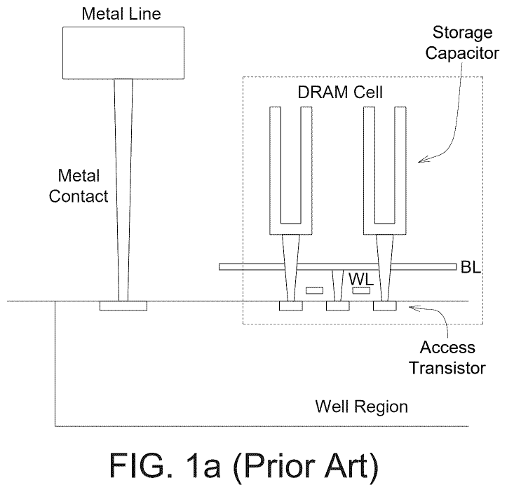

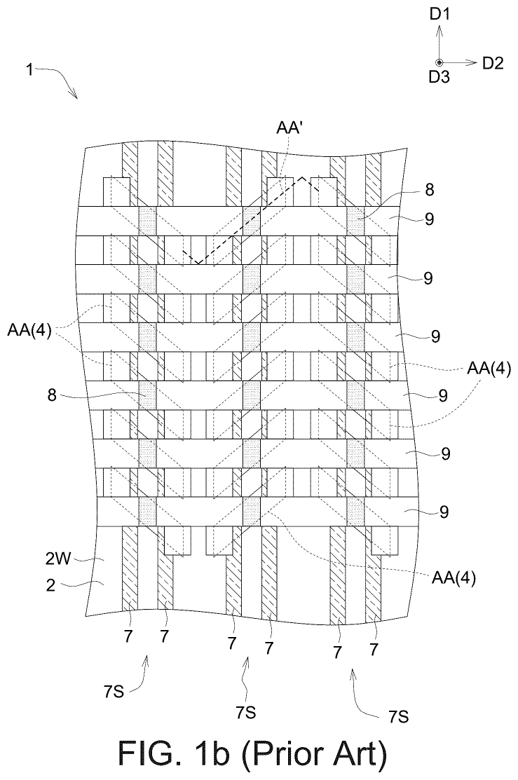

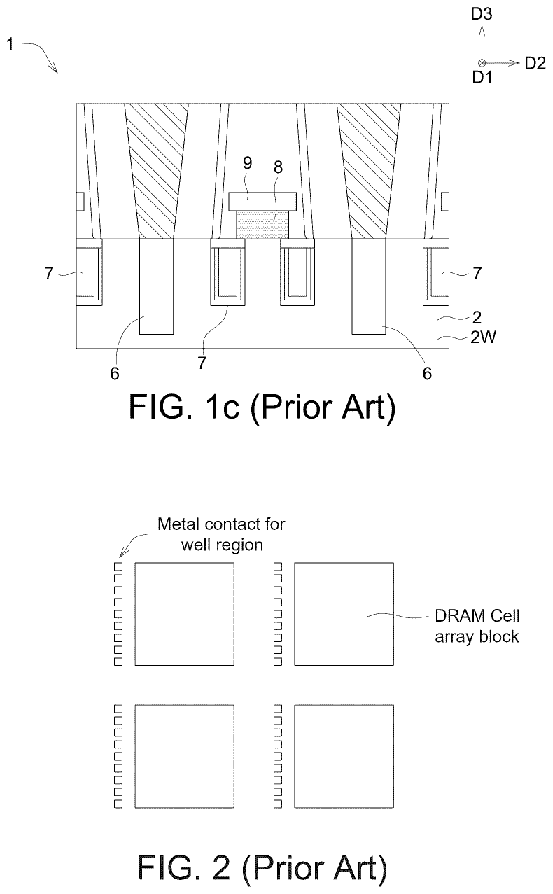

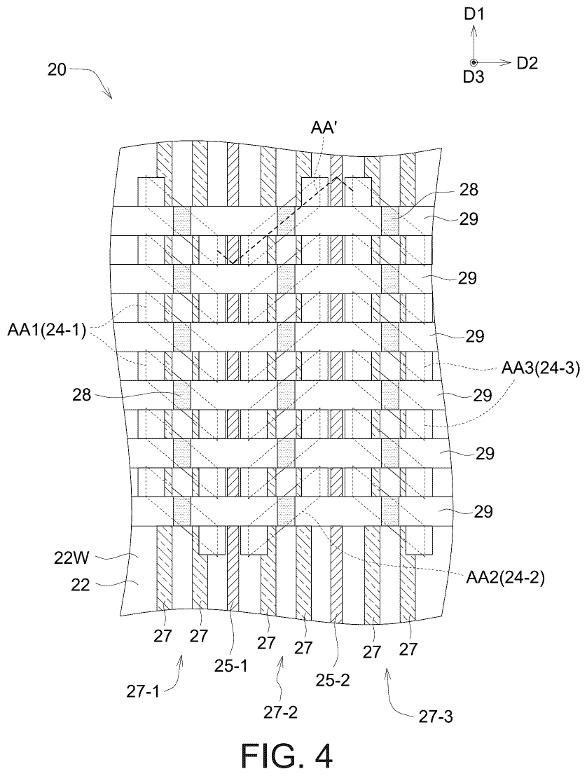

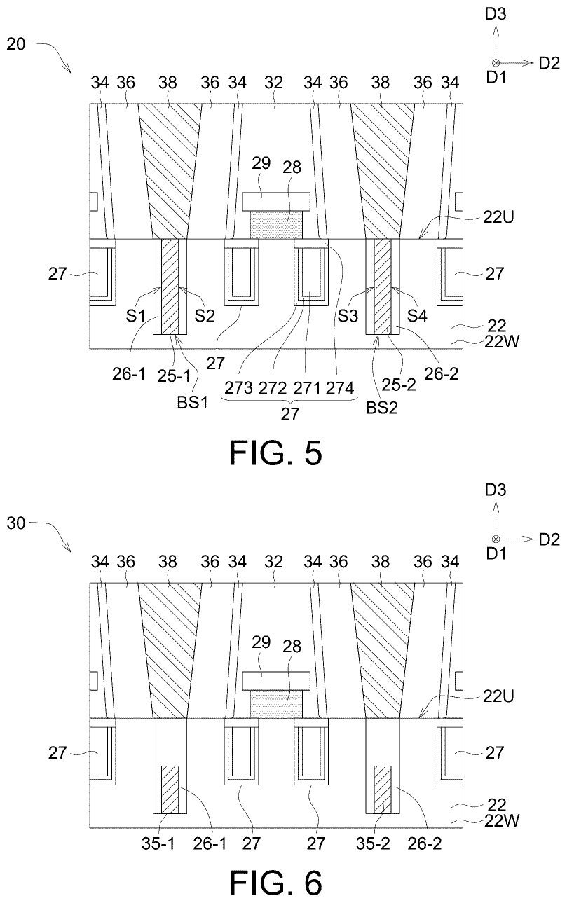

Referring to FIGS. 4 and 5, FIG. 4 illustrates a schematic top view of a DRAM cell structure 20 according to an embodiment of the present disclosure, and FIG. 5 is a schematic cross-sectional view of the DRAM cell structure 20 illustrated along the lines BB′ shown in FIG. 4. For clarity, the storage capacitor and the access transistor of the DRAM cell structure 20 is omitted in FIGS. 4 and 5; the components and the electrical connections of components in the DRAM cell structure 10 shown in FIG. 1 are also applicable to the DRAM cell structure 20 shown in FIG. 2. The number of components in the DRAM cell structure 20 is not limited to that shown in FIGS. 4 and 5. The DRAM cell structure 20 includes a semiconductor substrate 22, a first set of active areas 24-1, a second set of active areas 24-2, a third set of active areas 24-3, a first conductive interconnection structure 25-1, a second conductive interconnection structure 25-2, a first isolation structure 26-1, a second isolation structure 26-2, a first set of word lines 27-1, a second set of word lines 27-2, a third set of word lines 27-3 and bit lines 29. The semiconductor substrate 22 has a well region 22W and an original semiconductor surface 22U.

The first set of active areas 24-1, the second set of active areas 24-2 and the third set of active areas 24-3 are within the well region 22W of the semiconductor substrate 22. The first set of active areas 24-1 includes active areas AA1 arranged along a first direction D1 and separated from each other. The second set of active areas 24-2 includes active areas AA2 arranged along the first direction D1 and separated from each other. The third set of active areas 24-3 includes active areas AA3 arranged along the first direction D1 and separated from each other. The configuration of active areas AA1 of the first set of active areas 24-1 can be symmetrical to the configuration of active areas AA2 of the second set of active areas 24-2. The configuration of active areas AA1 of the first set of active areas 24-1 and the configuration of active areas AA2 of the second set of active areas 24-2 can be mirror images of each other. The configuration of active areas AA2 of the second set of active areas 24-2 can be symmetrical to the configuration of active areas AA3 of the third set of active areas 24-3. The configuration of active areas AA2 of the second set of active areas 24-2 and the configuration of active areas AA3 of the third set of active areas 24-2 can be mirror images of each other. In other embodiments, the configuration of active areas AA1 of the first set of active areas 24-1, the configuration of active areas AA2 of the second set of active areas 24-2 and the configuration of active areas AA3 of the third set of active areas 24-3 are the same. The shapes of the active areas AA1˜AA3 are not limited to those shown in FIG. 4. The first set of active areas 24-1, the second set of active areas 24-2 and the third set of active areas 24-3 are arranged along a second direction D2 different from the first direction D1. The second direction D2 can be perpendicular to the first direction D1. The access transistors of the DRAM cell structure 20 are formed in the active areas AA1˜AA3. The access transistors of the DRAM cell structure 20 are located within the well region 22W.

The first conductive interconnection structure 25-1, the second conductive interconnection structure 25-2, the first isolation structure 26-1 and the second isolation structure 26-2 are positioned in the semiconductor substrate 22. The first conductive interconnection structure 25-1, the second conductive interconnection structure 25-2, the first isolation structure 26-1 and the second isolation structure 26-2 can extend along the first direction D1. As shown in FIG. 5, the first conductive interconnection structure 25-1 and the second conductive interconnection structure 25-2 can be completely embedded in the semiconductor substrate 22. The first conductive interconnection structure 25-1 can be positioned within the first isolation structure 26-1. The second conductive interconnection structure 25-2 can be positioned within the second isolation structure 26-2. As shown in FIG. 5, the first conductive interconnection structure 25-1 can be embedded or buried in the first isolation structure 26-1, and the second conductive interconnection structure 25-2 can be embedded or buried in the second isolation structure 26-2. The first isolation structure 26-1, the second isolation structure 26-2, the first conductive interconnection structure 25-1, and the second conductive interconnection structure 25-2 can be below the original semiconductor surface 22U of the semiconductor substrate 22 in the third direction D3. The first, second and third directions D1, D2 and D3 can be perpendicular to each other. The upper surfaces of the first isolation structure 26-1, the second isolation structure 26-2, the first conductive interconnection structure 25-1, and the second conductive interconnection structure 25-2 can be coplanar with the original semiconductor surface 22U of the substrate. The first isolation structure 26-1 is positioned on a sidewall S1 and a sidewall S2 of the first conductive interconnection structure 25-1. The sidewall S2 of the first conductive interconnection structure 25-1 is opposite to the sidewall S1 of the first conductive interconnection structure 25-1. The sidewalls S1 and S2 of the first conductive interconnection structure 25-1 can be at least partially or completely covered by the first isolation structure 26-1. The sidewalls S1 and S2 of the first conductive interconnection structure 25-1 can be isolated from the semiconductor substrate 22 by the first isolation structure 26-1. The second isolation structure 26-2 is positioned on a sidewall S3 and a sidewall S4 of the second conductive interconnection structure 25-2. The sidewall S4 of the second conductive interconnection structure 25-2 is opposite to the sidewall S3 of the second conductive interconnection structure 25-2. The sidewalls S3 and S4 of the second conductive interconnection structure 25-2 can be at least partially or completely covered by the second isolation structure 26-2. The sidewalls S3 and S4 of the second conductive interconnection structure 25-2 can be isolated from the semiconductor substrate 22 by the second isolation structure 26-2.

A bottom surface BS1 of the first conductive interconnection structure 25-1 contacts the well region 22W of the semiconductor substrate 22. A bottom surface BS2 of the second conductive interconnection structure 25-2 contacts the well region 22W of semiconductor substrate 22. The bottom surfaces BS1 and BS2 of the first conductive interconnection structure 25-1 and the second conductive interconnection structure 25-2 can be lower than a bottom surface of the word line 27 in the third direction D3. The bottom surface of the word line 27 in the active region can be understood as a bottom surface of the gate structure of the access transistor. The first conductive interconnection structure 25-1 and the second conductive interconnection structure 25-2 are electrically connected to the well region 22W of the semiconductor substrate 22. The first conductive interconnection structure 25-1 and the second conductive interconnection structure 25-2 extend to a position close to a boundary of the well region. A bias voltage can be applied to the well region 22W through the first conductive interconnection structure 25-1 and the second conductive interconnection structure 25-2. The first conductive interconnection structure 25-1 and the second conductive interconnection structure 25-2 will connect out at memory cell array boundary.

The first conductive interconnection structure 25-1 and the first isolation structure 26-1 are between the first set of active areas 24-1 and the second set of active areas 24-2. The second conductive interconnection structure 25-2 and the second isolation structure 26-2 are between the second set of active areas 24-2 and the third set of active areas 24-3. The first set of active areas 24-1 can be separated from or electrically isolated from the second set of active areas 24-2 by the first isolation structure 26-1. The second set of active areas 24-2 can be separated from or electrically isolated from the third set of active areas 24-3 by the second isolation structure 26-2. The semiconductor substrate 22 may include or be made of a semiconductor material, such as silicon. The first conductive interconnection structure 25-1 and the second conductive interconnection structure 25-2 may include conductive materials, such as highly doped semiconductor material and/or metal. In an embodiment, the first conductive interconnection structure 25-1 and the second conductive interconnection structure 25-2 includes or be made of highly doped silicon, tungsten (W), titanium nitride (TIN), or combinations thereof. The well region 22W of the semiconductor substrate 22 is a doped region. The doping type of the doped region (well region 22W) in the semiconductor substrate 22, the doping type of the first conductive interconnection structure 25-1, and the doping type of the second conductive interconnection structure 25-2 may be the same. For example, the doped region (well region 22W) in the semiconductor substrate 22 has a P type doping, and the first conductive interconnection structure 25-1, and the doping type of the second conductive interconnection structure 25-2 includes or be made of P+ polycrystalline silicon or P+ selective epitaxial growth silicon. The first isolation structure 26-1 and the second isolation structure 26-2 may include a dielectric material, such as a spin-on dielectric (SOD) material.

The first set of word lines 27-1, the second set of word lines 27-2 and the third set of word lines 27-3 are positioned in the semiconductor substrate 22. The first set of word lines 27-1, the second set of word lines 27-2 and the third set of word lines 27-3 can be embedded in the semiconductor substrate 22. The first set of word lines 27-1, the second set of word lines 27-2 and the third set of word lines 27-3 can be below the original semiconductor surface 22U of the semiconductor substrate 22 in the third direction D3. The first set of word lines 27-1 extends across the first set of active areas 24-1. The second set of word lines 27-2 extends across the second set of active areas 24-2. The third set of word lines 27-3 extends across the third set of active areas 24-3. The first conductive interconnection structure 25-1 and the first isolation structure 26-1 are between the first set of word lines 27-1 and the second set of word lines 27-2. The second conductive interconnection structure 25-2 and the second isolation structure 26-2 are between the second set of word lines 27-2 and the third set of word lines 27-3. The first set of word lines 27-1 includes two word lines 27 extending along the first direction D1. The second set of word lines 27-1 includes two word lines 27 extending along the first direction D1. The third set of word lines 27-3 includes two word lines 27 extending along the first direction D1. The word lines 27 can be separated from each other. The word line 27 includes a conductive portion 271, a conductive layer 272, a gate dielectric layer 273, and a dielectric cover 274. The conductive layer 272 can be on the sidewall and the bottom surface of the conductive portion 271. The conductive portion 271 can be surrounded by the conductive layer 272. The conductive layer 272 can be between the conductive portion 271 and the gate dielectric layer 273. The gate dielectric layer 273 can be on the sidewall and the bottom surface of the conductive layer 272. The conductive portion 271 and the conductive layer 272 can be surrounded by the gate dielectric layer 273. The dielectric cover 274 can be on the upper surfaces of the conductive portion 271, the conductive layer 272 and the gate dielectric layer 273. The gate dielectric layer 273 and the dielectric cover 274 can contact the semiconductor substrate 22. The conductive portion 271 may include a conductive material, such as tungsten (W). The conductive layer 272 may include a conductive material, such as titanium nitride (TIN). The gate dielectric layer 273 may include a dielectric material, such as oxide. The dielectric cover 274 may include a dielectric material, such as nitride. In embodiment, the dielectric cover 274 includes silicon nitride.

The bit lines 29 are positioned on the semiconductor substrate 22. The bit lines 29 can be above the original semiconductor surface 22U of the semiconductor substrate 22 in the third direction D3. The bit lines 29 are arranged along the first direction D1 and separated from each other. Each bit line 29 can extend along the second direction D2. The bit lines 29 extend across the first set of active areas 24-1, the second set of active areas 24-2, the third set of active areas 24-3, the first conductive interconnection structure 25-1 and the second conductive interconnection structure 25-2. The bit line 29 may include a conductive material, such as metal or metal compound. The bit line 29 may include a combination of conductive materials. In an embodiment, the bit line 29 includes tungsten (W), tungsten silicide (WSix), titanium nitride (TiN) and titanium (Ti). The DRAM cell structure 20 further includes bit line contacts 28 positioned in intersections of active areas AA1, AA2 and AA3 and bit lines 29. The bit line contacts 28 can be between the bit lines 29 and the semiconductor substrate 22 and above the original semiconductor surface 22U of the semiconductor substrate 22. The bit line contact 28 may include a conductive material, such as polycrystalline silicon. Each bit line 29 can be electrically coupled to the corresponding doping region (not shown in the drawings) through the bit line contact 28, and the doping region can be between two word lines 27 of one set of word lines (e.g. the first set of word lines 27-1 or the second set of word lines 27-2 or the third set of word lines 27-3). The shape of the bit line contact 28 is not limited to that shown in FIG. 4.

The DRAM cell structure 20 can further includes a dielectric portion 32, a dielectric barrier layer 34, a storage node contact 36, and a dielectric film 38. The dielectric portion 32 can cover the bit line contact 28 and the bit line 29. The dielectric portion 32 can be above the semiconductor surface 22U of the semiconductor substrate 22. The dielectric portion 32 may contact the dielectric cover 274 of the word line 27. The dielectric portion 32 may be functioned as a hard mask. The dielectric portion 32 may include a dielectric material, such as nitride. In embodiment, the dielectric portion 32 includes silicon nitride. The dielectric barrier layer 34 can be on the outer surface of the dielectric portion 32. The dielectric barrier layer 34 can be above the semiconductor surface 22U of the semiconductor substrate 22. The dielectric barrier layer 34 may contact the dielectric cover 274 of the word line 27. The dielectric barrier layer 34 may include a dielectric material, such as nitride or oxynitride. In an embodiment, the dielectric barrier layer 34 includes a silicon nitride and silicon oxynitride. The storage node contact 36 can be on the outer surface of dielectric barrier layer 34. The dielectric barrier layer 34 can be between the dielectric portion 32 and the storage node contact 36. The storage node contact 36 can be above the semiconductor surface 22U of the semiconductor substrate 22. The storage capacitor of the DRAM cell structure 20 is electrically coupled to the source structure of the access transistor of the DRAM cell structure 20 through the storage node contact 36. The storage node contact 36 can be understood as a capacitor contact. The storage node contact 36 may include a conductive material, such as polycrystalline silicon. The dielectric film 38 can be above the semiconductor surface 22U of the semiconductor substrate 22. The dielectric film 38 can be on the outer surface of the storage node contact 36. The storage node contact 36 can be between the dielectric barrier layer 34 and the dielectric film 38. The dielectric film 38 can be between the first set of word lines 27-1 and the second set of word lines 27-2, and between the second set of word lines 27-2 and the third set of word lines 27-3. The dielectric film 38 can be positioned on the first isolation structure 26-1 and the second isolation structure 26-2. The dielectric film 38 may contact the first isolation structure 26-1 and the second isolation structure 26-2. The dielectric film 38 may contact the first conductive interconnection structure 25-1 and the second conductive interconnection structure 25-2. The dielectric film 38 may include a dielectric material, such as nitride. In an embodiment, the dielectric film 38 includes silicon nitride. The material of the dielectric film 38 can be different from the materials of the first isolation structure 26-1 and the second isolation structure 26-2.

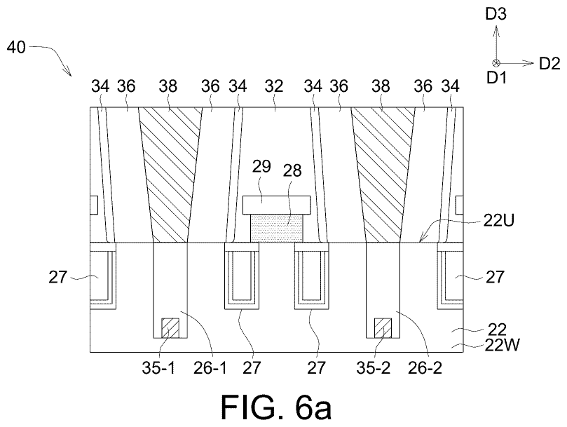

Referring to FIG. 6, FIG. 6 is a schematic cross-sectional view of a DRAM cell structure 30 according to another embodiment of the present disclosure. The difference between the DRAM cell structure 30 shown in FIG. 6 and the DRAM cell structure 20 shown in FIG. 5 is the size and/or configuration of the conductive interconnection structure relative to the isolation structure. The DRAM cell structure 30 includes the first conductive interconnection structure 35-1 in the first isolation structure 26-1 and the second conductive interconnection structure 35-2 in the second isolation structure 26-2. The first conductive interconnection structure 35-1 and the second conductive interconnection structure 35-2 are positioned in the semiconductor substrate 22 and can extend along the first direction D1. The first conductive interconnection structure 35-1 can be positioned within the first isolation structure 26-1. The second conductive interconnection structure 35-2 can be positioned within the second isolation structure 26-2. The first conductive interconnection structure 35-1 can be embedded or buried in the first isolation structure 26-1, and the second conductive interconnection structure 35-2 can be embedded or buried in the second isolation structure 26-2. The first conductive interconnection structure 35-1 and the second conductive interconnection structure 35-2 can be below the original semiconductor surface 22U of the semiconductor substrate 22 in the third direction D3. The upper surface of the first conductive interconnection structure 35-1 is covered by the first isolation structure 26-1 and lower than the original semiconductor surface 22U of the semiconductor substrate 22. The upper surface of the second conductive interconnection structure 35-2 is covered by the second isolation structure 26-2 and lower than the original semiconductor surface 22U of the semiconductor substrate 22. The first conductive interconnection structure 35-1 can be separated from the dielectric film 38 by the first isolation structure 26-1. The second conductive interconnection structure 35-2 can be separated from the dielectric film 38 by the second isolation structure 26-2. The first conductive interconnection structure 35-1 and the second conductive interconnection structure 35-2 are electrically connected to the well region 22W of the semiconductor substrate 22. The first conductive interconnection structure 35-1 and the second conductive interconnection structure 35-2 extend to a position close to a boundary of the well region. The materials of the first conductive interconnection structure 35-1 and the second conductive interconnection structure 35-2 can be the same as those of the first conductive interconnection structure 25-1 and the second conductive interconnection structure 25-2. Sizes of the first conductive interconnection structure 35-1 and the second conductive interconnection structure 35-2 in the third direction D3 can be smaller than Sizes of the first conductive interconnection structure 25-1 and the second conductive interconnection structure 25-2 in the third direction D3. With the size and/or configuration of the first conductive interconnection structure 35-1 and the second conductive interconnection structure 35-2, the coupling effect between the conductive interconnection structures and the word lines can be reduced.

The upper surface of the conductive interconnection structure according to the present disclosure can be coplanar with the original semiconductor surface 22U of the semiconductor substrate 22 (as shown in FIG. 5), or can be lower than the original semiconductor surface 22U of the semiconductor substrate 22 and higher than the bottom surface of the gate structure (as shown in FIG. 6), or can be coplanar with the bottom surface of the gate structure, or can be lower than the bottom surface of the gate structure (as shown FIG. 6a). In the DRAM cell structure 40 shown in FIG. 6a, the upper surface of the first conductive interconnection structure 35-1 is covered by the first isolation structure 26-1 and lower than the bottom surface of the gate structure (the bottom surface of the word line 27), and the upper surface of the second conductive interconnection structure 35-2 is covered by the second isolation structure 26-2 and lower than the bottom surface of the gate structure (the bottom surface of the word line 27).

The present disclosure uses buried/embedded metal or highly doped silicon as the conductive interconnection structure (e.g. the first conductive interconnection structure 25-1, the second conductive interconnection structure 25-2, the first conductive interconnection structure 35-1 and the second conductive interconnection structure 35-2) for electrical connection to the well region to get a strong connection to each memory cell with effective low resistance, so that the performance of the access transistor is completely unaffected by changes in the doping concentration of the well region, the DRAM cell structure and the size of the DRAM cell array.

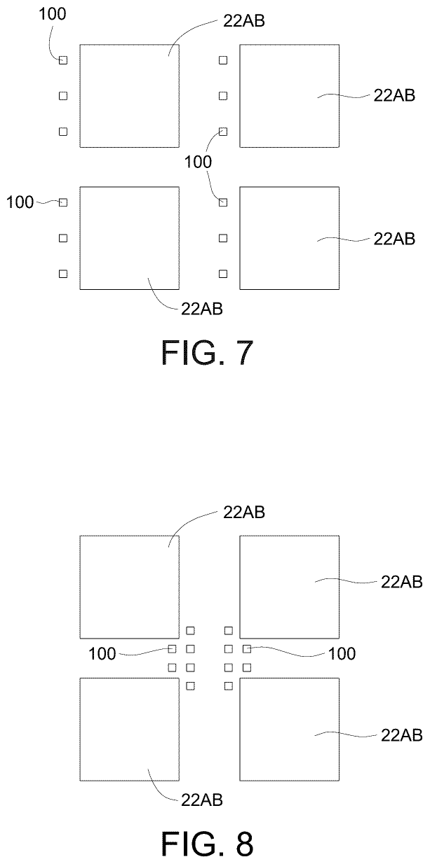

In an embodiment, the semiconductor substrate 22 further includes one or more DRAM cell array blocks 22AB accommodating the access transistors, and the conductive interconnection structure according to the present disclosure can extend to a position close to a boundary of the DRAM cell array block 22AB; the DRAM cell structure can further include one or more metal contacts 100 electrically connected to the conductive interconnection structure, as shown in FIG. 7 and FIG. 8. FIG. 7 illustrates an arrangement of conductive interconnection structures for DRAM cell array blocks 22AB according to some embodiments of the present disclosure. FIG. 8 illustrates an arrangement of conductive interconnection structures for DRAM cell array blocks 22AB according to some embodiments of the present disclosure. The DRAM cell array block 22AB accommodates the access transistors of the DRAM cell structure. As compared with the conventional arrangement of metal contacts shown in FIG. 2, the conductive interconnection structures (e.g. the first conductive interconnection structure 25-1, the second conductive interconnection structure 25-2, the first conductive interconnection structure 35-1 and the second conductive interconnection structure 35-2) according to the present disclosure can be flexibly arranged on one side of the DRAM cell array block 22AB (as show in FIG. 7) or between multiple DRAM cell array blocks 22AB (as show in FIG. 8) or only at corners of DRAM cell array blocks 22AB without around DRAM cell array boundary (as show in FIG. 8), and the number of the metal contacts 100 can be reduced while providing good and stable electrical connections with low resistance to the well region of the DRAM cell structure to apply stable voltage to each memory cell. As compared with the conventional arrangement of metal contacts shown in FIG. 2, the density of the metal contacts according to the present disclosure in bit line sense amplifier (SA) or word line driver (WLD) area around DRAM cell array block boundary can be reduced. In the conventional arrangement of metal contacts shown in FIG. 2, there is no specific connection to the well region in each DRAM cell, and the DRAM cell array blocks use metal contacts to connect the well regions to voltage source rather than use the well region to distribute the voltage to each DRAM cell. The DRAM cell array block shown in FIGS. 2, 7 and 8 includes a plurality of DRAM cells, such as 512×512 DRAM cells.

Some advantages of the DRAM cell structure of the present disclosure are described in the following:
(1) Electrical connection to each DRAM cell for solid voltage supply to the well region can be achieved.
(2) Low resistance of electrical connection to well region of each DRAM cell can be achieved without being affected by change in the doping concentration of substrate and/or change in cell structure.
(3) Low resistance of electrical connection to well region of each DRAM cell can be achieved without being affected by increasing the size of the DRAM cell array block. For example, even if the size of the DRAM cell array block is increased from 512×512 to 688×1024, low resistance of electrical connection to well region of each DRAM cell can still be achieved.
(4) With the good electrical and stable electrical connection to the well region with low resistance, the area of the well connection (i.e. the area used to arrange conductive interconnection structures) can be reduced and more feasibility for bit line sense amplifier or word line driver area layout arrangement can be obtained.
(5) DRAM chip size can be reduced by increasing the size of the DRAM cell array block (for example, the size of the DRAM cell array block can be increased from 512×512 to 688×1024). As such, the number of the DRAM cell array block can be reduced, and periphery circuit or bit line sense amplifier or word line driver area can be reduced by removing well connections.

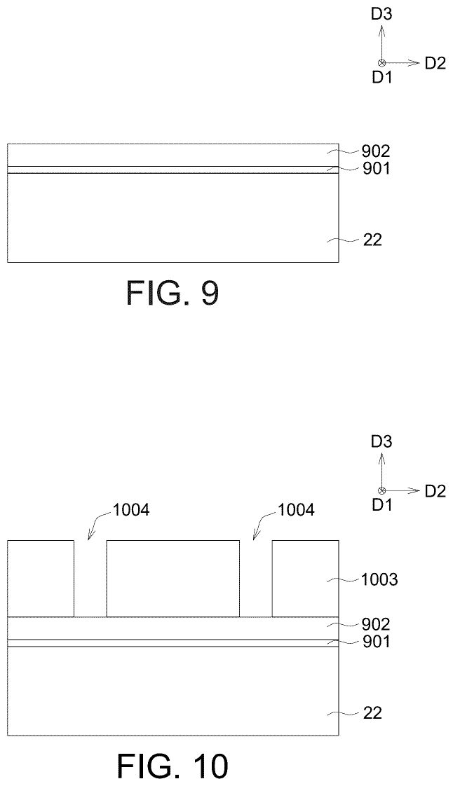

FIG. 9 to FIG. 19 illustrate schematic cross-sectional views of structures at various stages of a method for manufacturing a DRAM cell structure according to an embodiment of the present disclosure.

FIG. 9 illustrates a schematic cross-sectional view of a structure at a stage of the manufacturing method. A semiconductor substrate 22 is provided. A pad-oxide layer 901 and a pad-nitride layer 902 are sequentially formed above the semiconductor substrate 22 through deposition processes to define the active areas. The pad-oxide layer 901 may include oxide such as silicon oxide. The pad-nitride layer 902 may include nitride such as silicon nitride.

FIG. 10 illustrates a schematic cross-sectional view of a structure at a stage of the manufacturing method. A photo-resistance layer 1003 is formed on the pad-nitride layer 902 through a deposition process and patterned to define trenches 1004 in the photo-resistance layer 1003. The trenches 1004 extend along the third direction D3 and expose a portion of the pad-nitride layer 902.

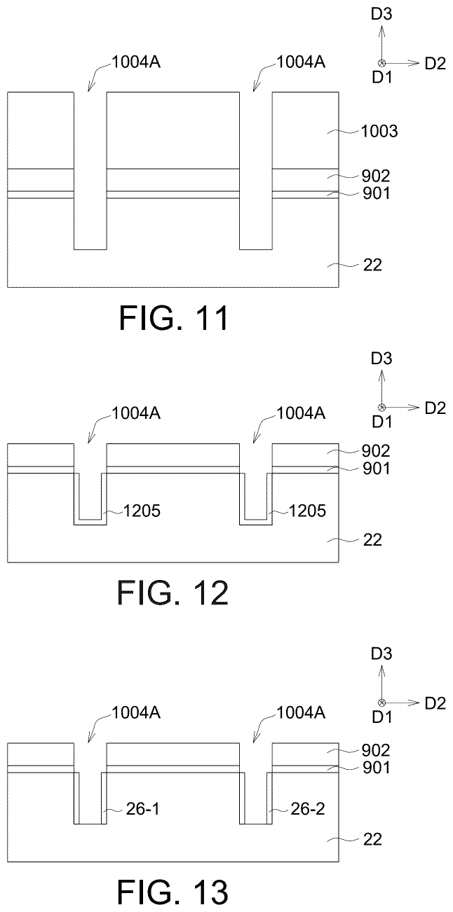

FIG. 11 illustrates a schematic cross-sectional view of a structure at a stage of the manufacturing method. Trenches 1004A are formed in the semiconductor substrate 22. The trenches 1004A extend along the third direction D3 and expose a portion of the pad-oxide layer 901, a portion of the pad-nitride layer 902, and a portion of the semiconductor substrate 22. The position of the trenches 1004 can correspond to the position of the trenches 1004A. The trenches 1004A can be formed by performing an etching process to remove a portion of the pad-oxide layer 901, a portion of the pad-nitride layer 902, and a portion of the semiconductor substrate 22 through the trenches 1004. A length of the trench 1004A in the third direction D3 can be greater than a length of the trench 1004 in the third direction D3. The active area can be defined between the trenches 1004A and in the semiconductor substrate 22. The trenches 1004A are near the active area.

FIG. 12 illustrates a schematic cross-sectional view of a structure at a stage of the manufacturing method. The photo-resistance layer 1003 is removed through an etching process or a polishing process, and a dielectric material 1205 is formed on the sidewalls and the bottoms of the trenches 1004A through a deposition process. The dielectric material 1205 can be grown along the semiconductor substrate 22 exposed by the trenches 1004A. The upper surface of the dielectric material 1205 can be lower than the upper surface of the pad-nitride layer 902 in the third direction D3. The upper surface of the dielectric material 1205 can be coplanar with the upper surface of the pad-oxide layer 901, or coplanar with the upper surface of the semiconductor substrate 22, or lower than the upper surface of the pad-oxide layer 901 and higher than the upper surface of the semiconductor substrate 22 in the third direction D3. The dielectric material 1205 may include a dielectric material, such as a spin-on dielectric (SOD) material.

FIG. 13 illustrates a schematic cross-sectional view of a structure at a stage of the manufacturing method. A portion of the dielectric material 1205 on the bottoms of the trenches 1004A is removed through an etching process and a portion of the dielectric material 1205 on the sidewalls of the trenches 1004A are retained. A portion of the semiconductor substrate 22 is exposed by the trench 1004A. The retained portion of the dielectric material 1205 on the sidewalls of the trenches 1004A can be defined as the first isolation structure 26-1 and the second isolation structure 26-2.

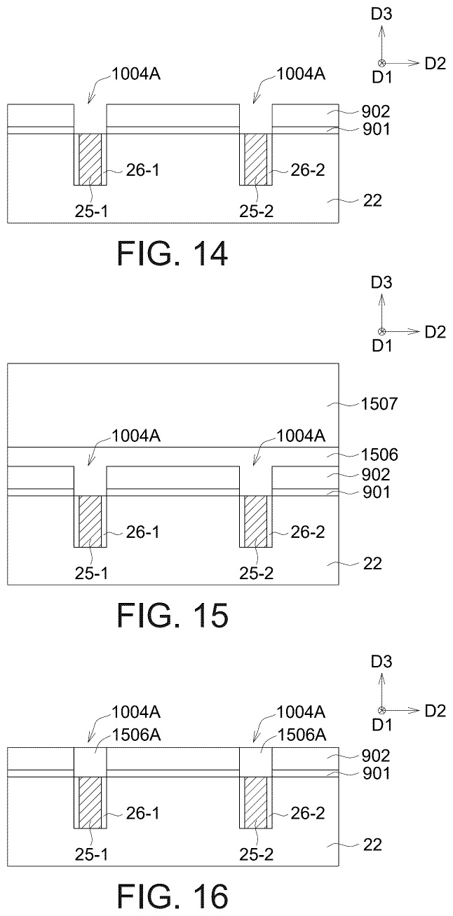

FIG. 14 illustrates a schematic cross-sectional view of a structure at a stage of the manufacturing method. A conductive material is filled in the trenches 1004A and on the upper surface of the pad-nitride layer 902 through a deposition process, and a portion of the conductive material above the upper surface of the semiconductor substrate 22 is removed through an etching back process to form the first conductive interconnection structure 25-1 and the second conductive interconnection structure 25-2 in the trenches 1004A respectively. The first isolation structure 26-1 and the first conductive interconnection structure 25-1 are in one of the trenches 1004A, and the second isolation structure 26-2 and the second conductive interconnection structure 25-2 are in another one of the trenches 1004A. The upper surfaces of the first isolation structure 26-1, the second isolation structure 26-2, the first conductive interconnection structure 25-1 and the second conductive interconnection structure 25-2 can be coplanar or have the same height in the third direction D3.

FIG. 15 illustrates a schematic cross-sectional view of a structure at a stage of the manufacturing method. A SOD film 1506 and a HDP (high density plasma) oxide film 1507 are sequentially formed on the pad-nitride layer 902 through deposition processes. A portion of the SOD film 1506 is in the trenches 1004A and may contact the first isolation structure 26-1, the second isolation structure 26-2, the first conductive interconnection structure 25-1 and the second conductive interconnection structure 25-2. In an embodiment, the formation of the SOD film 1506 may include a pre-growth process of oxide.

FIG. 16 illustrates a schematic cross-sectional view of a structure at a stage of the manufacturing method. A portion of the SOD film 1506 above the upper surface of the pad-nitride layer 902 and the HDP oxide film 1507 are removed through a polishing process to expose the pad-nitride layer 902, and a portion of the SOD film 1506 in the trenches 1004A are retained. The retained portion of the SOD film 1506 can be defined as the SOD film 1506A. The upper surface of the SOD film 1506A and the upper surface of the pad-nitride layer 902 can be coplanar.

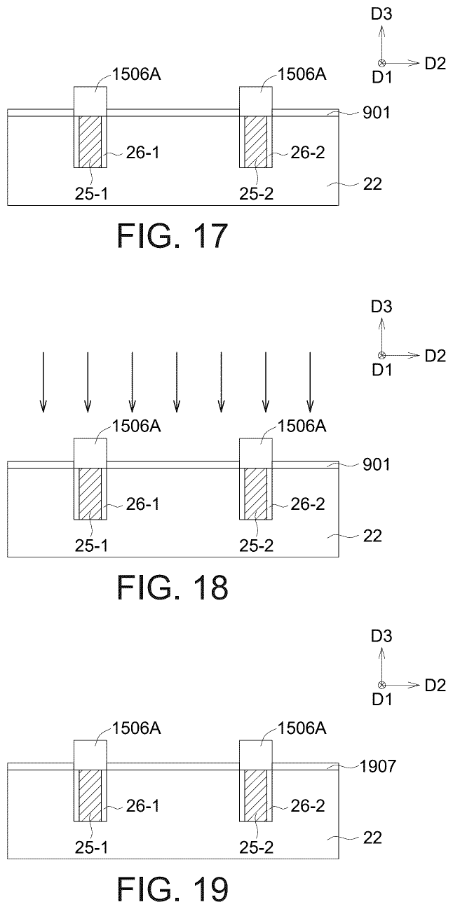

FIG. 17 illustrates a schematic cross-sectional view of a structure at a stage of the manufacturing method. The pad-nitride layer 902 is removed through an etching process. Sidewalls of the SOD film 1506A and the upper surface of the pad-oxide layer 901 are exposed.

FIG. 18 illustrates a schematic cross-sectional view of a structure at a stage of the manufacturing method. An ion implantation process (represented by arrows) is performed to define well region and channels of the access transistors.

FIG. 19 illustrates a schematic cross-sectional view of a structure at a stage of the manufacturing method. The pad-oxide layer 901 is removed through an etching process to expose the semiconductor substrate 22, and a gate dielectric film 1907 is formed on the semiconductor substrate 22 through an epitaxial growth process. The gate dielectric film 1907 may contact the semiconductor substrate 22 and the SOD film 1506A. Therefore, a semiconductor structure including conductive interconnection structures within isolation structures is provided. Manufacturing steps for forming transistors in the active areas can be performed after the stage shown in FIG. 19.

FIG. 20 to FIG. 26 illustrate schematic cross-sectional views of structures at various stages of a method for manufacturing a DRAM cell structure according to another embodiment of the present disclosure. In an embodiment, the manufacturing steps illustrated with reference to FIG. 20 to FIG. 26 can be performed after the manufacturing steps illustrated with reference to FIG. 9 to FIG. 12.

FIG. 20 illustrates a schematic cross-sectional view of a structure at a stage of the manufacturing method. A portion of the dielectric material 1205 on the bottoms of the trenches 1004A is removed through an etching process and a portion of the dielectric material 1205 on the sidewalls of the trenches 1004A are retained. A portion of the semiconductor substrate 22 is exposed by the trench 1004A. The retained portion of the dielectric material 1205 on the sidewalls of the trenches 1004A can be defined as the dielectric material 2005.

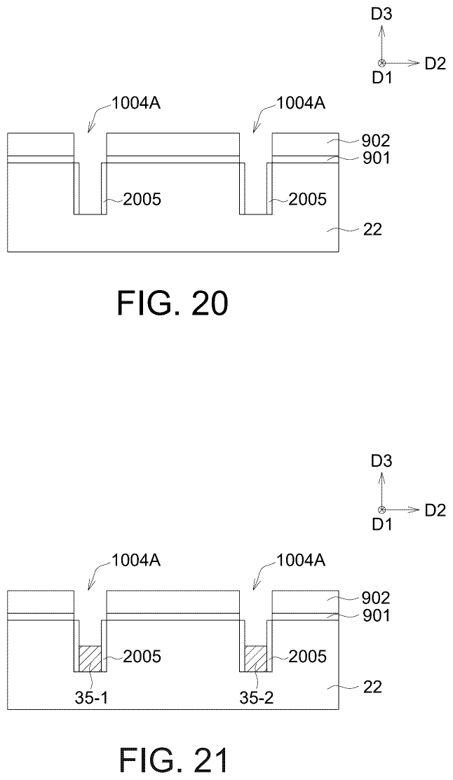

FIG. 21 illustrates a schematic cross-sectional view of a structure at a stage of the manufacturing method. A conductive material is filled in the trenches 1004A and on the upper surface of the pad-nitride layer 902 through a deposition process; a portion of the conductive material above the upper surface of the semiconductor substrate 22 and a portion of the conductive material in the upper portions of the trenches 1004A are removed through an etching back process to form the first conductive interconnection structure 35-1 and the second conductive interconnection structure 35-2 in the trenches 1004A respectively. The upper surface of the dielectric material 2005 can be higher than the upper surfaces of the first conductive interconnection structure 35-1 and the second conductive interconnection structure 35-2 in the third direction D3. The first conductive interconnection structure 35-1 and the second conductive interconnection structure 35-2 can be formed on sidewalls of the dielectric material 2005.

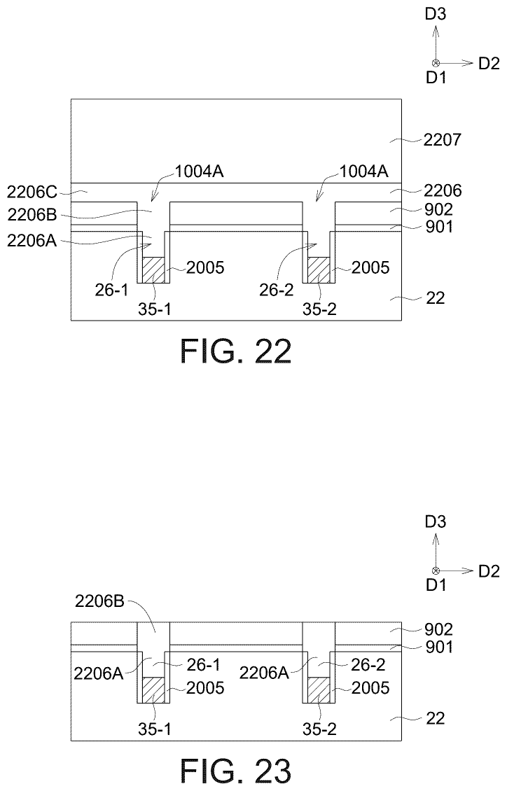

FIG. 22 illustrates a schematic cross-sectional view of a structure at a stage of the manufacturing method. A dielectric material 2206 and a HDP (high density plasma) oxide film 2207 are sequentially formed on the pad-nitride layer 902 through deposition processes. The dielectric material 2206 may include a first dielectric portion 2206A in the trenches 1004A and in the semiconductor substrate 22, a second dielectric portion 2206B in the trenches 1004A and above the semiconductor substrate 22, and a third dielectric portion 2206C above the pad-nitride layer 902. The first dielectric portion 2206A of the dielectric material 2206 is in the upper portion of the trenches 1004A. The first dielectric portion 2206A of the dielectric material 2206 is on an upper surface of the first conductive interconnection structure 35-1 and on an upper surface of the second conductive interconnection structure 35-2. The first dielectric portion 2206A of the dielectric material 2206 can be on the sidewall of the dielectric material 2005, and can contact the dielectric material 2005, the first conductive interconnection structure 35-1 and the second conductive interconnection structure 35-2. The second dielectric portion 2206B of the dielectric material 2206 can be on the sidewalls of the pad-oxide layer 901 and the pad-nitride layer 902. The second dielectric portion 2206B of the dielectric material 2206 may contact the pad-oxide layer 901, the pad-nitride layer 902, the first dielectric portion 2206A and the third dielectric portion 2206C. The third dielectric portion 2206C of the dielectric material 2206 may contact and be between the pad-nitride layer 902 and the HDP oxide film 2207. In an embodiment, the formation of the dielectric material 2206 may include a pre-growth process of oxide. The dielectric material 2206 may include a dielectric material, such as a spin-on dielectric (SOD) material. The first dielectric portion 2206A in one of the trenches 1004A and the dielectric material 2005 in the same trench 1004A can form (or be defined as) the first isolation structure 26-1, and first dielectric portion 2206A in another one of the trenches 1004A and the dielectric material 2005 in the same trench 1004A can form (or be defined as) the second isolation structure 26-2.

FIG. 23 illustrates a schematic cross-sectional view of a structure at a stage of the manufacturing method. The third dielectric portion 2206C of the dielectric material 2206 and the HDP oxide film 2207 are removed through a polishing process to expose the pad-nitride layer 902, and the first dielectric portion 2206A and the second dielectric portion 2206B are retained. The upper surface of the second dielectric portion 2206B and the upper surface of the pad-nitride layer 902 can be coplanar.

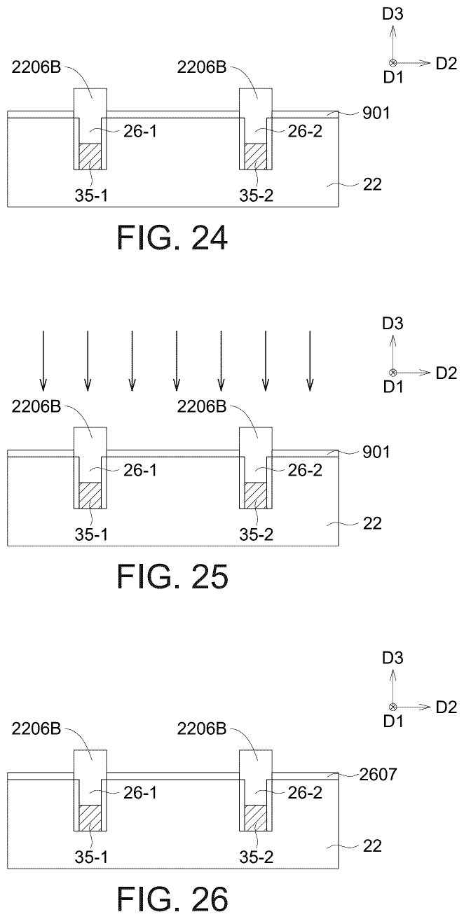

FIG. 24 illustrates a schematic cross-sectional view of a structure at a stage of the manufacturing method. The pad-nitride layer 902 is removed through an etching process. Sidewalls of the second dielectric portion 2206B and the upper surface of the pad-oxide layer 901 are exposed.

FIG. 25 illustrates a schematic cross-sectional view of a structure at a stage of the manufacturing method. An ion implantation process (represented by arrows) is performed to define well regions and channels of the access transistors.

FIG. 26 illustrates a schematic cross-sectional view of a structure at a stage of the manufacturing method. The pad-oxide layer 901 is removed through an etching process to expose the semiconductor substrate 22, and a gate dielectric film 2607 is formed on the semiconductor substrate 22 through an epitaxial growth process. The gate dielectric film 2607 may contact the semiconductor substrate 22 and the second dielectric portion 2206B. Therefore, a semiconductor structure including conductive interconnection structures within isolation structures is provided. Manufacturing steps for forming transistors in the active areas can be performed after the stage shown in FIG. 26.

It is noted that the structures and methods as described above are provided for illustration. The disclosure is not limited to the configurations and procedures disclosed above. Other embodiments with different configurations of known elements can be applicable, and the exemplified structures could be adjusted and changed based on the actual needs of the practical applications. It is, of course, noted that the configurations of figures are depicted only for demonstration, not for limitation. Thus, it is known by people skilled in the art that the related elements and layers in a semiconductor structure, the shapes or positional relationship of the elements and the procedure details could be adjusted or changed according to the actual requirements and/or manufacturing steps of the practical applications.

While the disclosure has been described by way of example and in terms of the exemplary embodiment(s), it is to be understood that the disclosure is not limited thereto. On the contrary, it is intended to cover various modifications and similar arrangements and procedures, and the scope of the appended claims therefore should be accorded the broadest interpretation so as to encompass all such modifications and similar arrangements and procedures.

What is claimed is:

1. A DRAM cell structure, comprising:
a semiconductor substrate having a well region and an original semiconductor surface;
an access transistor located within the well region and having a gate structure;
a bit line electrically coupled to the access transistor;
a storage capacitor electrically coupled to the access transistor;
a word line electrically coupled to the gate structure of the access transistor;
an isolation structure within the well region and surrounding the access transistor; and
a conductive interconnection structure positioned within the isolation structure and electrically connected to the well region of the semiconductor substrate.

2. The DRAM cell structure according to claim 1, wherein a bottom surface of the conductive interconnection structure contacts the well region of the semiconductor substrate.

3. The DRAM cell structure according to claim 1, wherein a bottom surface of the conductive interconnection structure is lower than a bottom surface of the gate structure.

4. The DRAM cell structure according to claim 1, wherein an upper surface of the conductive interconnection structure is covered by the isolation structure and lower than the original semiconductor surface of the semiconductor substrate.

5. The DRAM cell structure according to claim 4, wherein the upper surface of the conductive interconnection structure is lower than a bottom surface of the gate structure.

6. The DRAM cell structure according to claim 1, further comprising a trench in the substrate, wherein the isolation structure and the conductive interconnection structure are in the trench.

7. The DRAM cell structure according to claim 1, wherein the word line and the conductive interconnection structure extend along a first direction, and the bit line extends along a second direction different from the first direction.

8. The DRAM cell structure according to claim 1, wherein the conductive interconnection structure has a first sidewall and a second sidewall opposite to the first sidewall, both the first sidewall and the second sidewall are covered by the isolation structure.

9. The DRAM cell structure according to claim 1, wherein the conductive interconnection structure extends to a position close to a boundary of the well region.

10. The DRAM cell structure according to claim 1, wherein the semiconductor substrate further comprises a cell array block accommodating the access transistor, and the conductive interconnection structure extends to a position close to a boundary of the cell array block.

11. The DRAM cell structure according to claim 10, further comprising a metal contact close to the boundary of the cell array block, wherein the metal contact electrically connected to the conductive interconnection structure.

12. The DRAM cell structure according to claim 1, wherein the conductive interconnection structure comprises highly doped silicon, tungsten, titanium nitride, or combinations thereof.

13. A DRAM cell structure, comprising:
a semiconductor substrate with a well region and an original semiconductor surface;
a first set of active areas within the well region;
a second set of active areas within the well region;
a first word line extending across the first set of active areas;
a second word line extending across the second set of active areas;
an isolation structure between the first set of active areas and the second set of active areas; and
a conductive interconnection structure positioned within the isolation structure and electrically connected to the well region.

14. The DRAM cell structure according to claim 13, wherein the first word line, the second word line, and the conductive interconnection structure extend along a first direction.

15. The DRAM cell structure according to claim 13, wherein a bottom surface of the conductive interconnection structure contacts the well region of the semiconductor substrate.

16. The DRAM cell structure according to claim 14, wherein the semiconductor substrate further comprises a cell array block accommodating the first set of active areas and the second set of active areas, and the conductive interconnection structure extends to a position close to a boundary of the cell array block.

17. The DRAM cell structure according to claim 16, further comprising a metal contact outside the boundary of the cell array block, wherein the metal contact electrically connected to the conductive interconnection structure.

18. The DRAM cell structure according to claim 13, wherein an upper surface of the conductive interconnection structure is covered by the isolation structure.

19. A method for manufacturing a DRAM cell structure, comprising:
providing a semiconductor substrate with an original semiconductor surface;
defining an active area;
forming a trench in the semiconductor substrate and near the active area;
forming an isolation structure and a conductive interconnection structure in the trench, wherein the conductive interconnection structure are surrounded by the isolation structure; and
forming a well region accommodating the active area;
wherein a bottom surface of the conductive interconnection structure contacts the well region of the semiconductor substrate, and the conductive interconnection structure extends along a first direction and remote from the active area.

20. The method according to claim 19, wherein forming the isolation structure and the conductive interconnection structure in the trench comprises:
forming a first dielectric material covering sidewalls of the trench;
forming the conductive interconnection structure surrounded by the first dielectric material; and
forming a second dielectric material on an upper surface of the conductive interconnection structure,
wherein the first dielectric material and the second dielectric material form the isolation structure.
